(19) United States
(12) Patent Application Publication
(10) Pub. No.: US 2026/0343745 A1
(43) Pub. Date: Oct. 29, 2026

(54) FLEXIBLE CIRCUIT BOARD, COF MODULE, AND ELECTRONIC DEVICE INCLUDING SAME

(71) Applicant: LG INNOTEK CO., LTD., Seoul (KR)

(72) Inventors: Se Mi Na JEON, Seoul (KR); Ji Hyo PARK, Seoul (KR); Sung Min CHAE, Seoul (KR)

(21) Appl. No.: 19/106,132

(22) PCT Filed: Aug. 14, 2023
(86) PCT No.: PCT/KR2023/012057

§ 371 Date: Feb. 24, 2025

(30) Foreign Application Priority Data
Aug. 24, 2022 (KR) 10-2022-0106425

(51) Int. Cl. H05K 1/11

(52) U.S. Cl. CPC H05K 1/118; H05K 1/111; H05K 2201/10128

(57) ABSTRACT

A flexible circuit board according to an embodiment includes a substrate including a first surface and a second surface opposite to the first surface; a circuit pattern disposed on the first surface of the substrate; and a protective layer on the circuit pattern, wherein the circuit pattern includes a first circuit pattern and a second circuit pattern, wherein the first circuit pattern includes a first pad part configured to be electrically connected to a chip, a second pad part configured to be electrically connected to a printed circuit board, and a first wiring part connected to the first pad part and the second pad part, wherein the second circuit pattern includes a third pad part configured to be electrically connected to the chip, a fourth pad part configured to be electrically connected to a display panel, and a second wiring part connected to the third pad part and the fourth pad part, wherein the first surface of the substrate includes a first bonding region on which the second pad part is disposed and a second bonding region on which the fourth pad part is disposed, and wherein a dummy pattern is disposed on the second surface of the substrate corresponding to the second bonding region.

### TECHNICAL FIELD

An embodiment relates to a flexible circuit board, a COF module and an electronic device including the same. The flexible circuit board may be a flexible circuit board for COF.

### BACKGROUND ART

Recently, various electronic products are becoming thinner, smaller, and lighter. Accordingly, various studies are being conducted to mount semiconductor chips in a narrow region of electronic products at high density.

COF (Chip On Film) uses a flexible substrate. Accordingly, the COF is applied to flexible displays. That is, a COF method is applied to various wearable electronic devices. In addition, the COF can implement a fine pitch. Therefore, the COF can be applied to a high-resolution display.

The COF is formed by mounting a semiconductor chip on a flexible circuit board in a form of a thin film. For example, the semiconductor chip may include an integrated circuit (IC) chip or a large scale integrated circuit (LSI) chip.

Meanwhile, the chip is connected to an external printed circuit board and a display panel by a circuit pattern. For example, a pad part is disposed on one end and the other end of the circuit pattern, respectively. In addition, one pad part is electrically connected to a terminal of the chip. In addition, another pad part is connected to a terminal of a printed circuit board and a terminal of the display panel. Accordingly, the chip, the printed circuit board, and the display panel are electrically connected by the COF. In addition, a signal is transmitted to the display panel by the circuit pattern.

The COF (Chip On Film) type flexible circuit board is applied to a flexible display. Accordingly, the flexible circuit board is bent in one direction.

When the flexible circuit board is bent, a crack may occur in the circuit pattern located in a bending region. Therefore, the electrical characteristics of the flexible circuit board may be reduced.

Therefore, a flexible circuit board with a new structure capable of solving above problems is required.

### DISCLOSURE

### Technical Problem

An embodiment provides a flexible circuit board having improved reliability.

### Technical Solution

A flexible circuit board according to an embodiment includes a substrate including a first surface and a second surface opposite to the first surface; a circuit pattern disposed on the first surface of the substrate; and a protective layer on the circuit pattern, wherein the circuit pattern includes a first circuit pattern and a second circuit pattern, wherein the first circuit pattern includes a first pad part configured to be electrically connected to a chip, a second pad part configured to be electrically connected to a printed circuit board, and a first wiring part connected to the first pad part and the second pad part, wherein the second circuit pattern includes a third pad part configured to be electrically connected to the chip, a fourth pad part configured to be electrically connected to a display panel, and a second wiring part connected to the third pad part and the fourth pad part, wherein the first surface of the substrate includes a first bonding region on which the second pad part is disposed and a second bonding region on which the fourth pad part is disposed, and wherein a dummy pattern is disposed on the second surface of the substrate corresponding to the second bonding region.

### Advantageous Effects

The flexible circuit board according to the embodiment includes a dummy pattern.

In detail, the flexible circuit board according to the embodiment includes a circuit pattern disposed on a first surface, and a dummy pattern disposed on a second surface.

The dummy pattern is partially disposed on the second surface. The dummy pattern is disposed in a region entirely or partially corresponding to a pad part connected to a display panel.

The flexible circuit board forms a COF module by mounting a chip. In addition, the flexible circuit board is bent in one direction. Accordingly, stress may be generated in the flexible circuit board. The stress may be transmitted in a direction toward the pad part.

Accordingly, when the pad part and a terminal part of the display panel are bonded, a corrosion protection layer that prevents corrosion of the pad part may be peeled off. In addition, a crack may be generated in the pad part exposed by the peeling of the corrosion protection layer due to stress.

The flexible circuit board according to the embodiment includes a dummy pattern disposed on a second surface corresponding to the pad part or the pad part and the wiring part. The peeling of the corrosion protection layer can be prevented by the dummy pattern. In addition, the cracking of the pad part can be prevented by the dummy pattern.

Therefore, the flexible circuit board according to the embodiment can have improved bending characteristics and reliability.

### DESCRIPTION OF DRAWINGS

FIG. 1 is a top view of a flexible circuit board according to an embodiment.

FIG. 2 and FIG. 3 are cross-sectional views taken along region A-A′ of FIG. 1.

FIG. 4 is a cross-sectional view taken along region B-B′ of FIG. 1.

FIG. 5 is a cross-sectional view taken along region C-C′ of FIG. 1.

FIG. 6 is an enlarged view of a bottom view of a flexible circuit board in a D region of FIG. 1.

FIG. 7 is a cross-sectional view taken along region E-E′ of FIG. 6.

FIG. 8 is another enlarged view of a bottom view of a flexible circuit board in a D region of FIG. 1.

FIG. 9 is a cross-sectional view taken along region F-F′ of FIG. 8.

FIG. 10 is another enlarged view of a bottom view of a flexible circuit board in a D region of FIG. 1.

FIG. 11 is a cross-sectional view taken along region G-G′ of FIG. 10.

FIGS. 12 to 14 are other enlarged views of a bottom view of a flexible printed circuit board of a D region of FIG. 1.

FIG. 15 is a top view of a COF module according to an embodiment.

FIG. 16 is a cross-sectional view showing a connection relationship of a COF module including a flexible printed circuit board according to an embodiment.

FIGS. 17 to 19 are drawings of an electronic device including a flexible printed circuit board according to an embodiment.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, a flexible circuit board, a COF module, and an electronic device including the same according to an embodiment will be described with reference to the drawings.

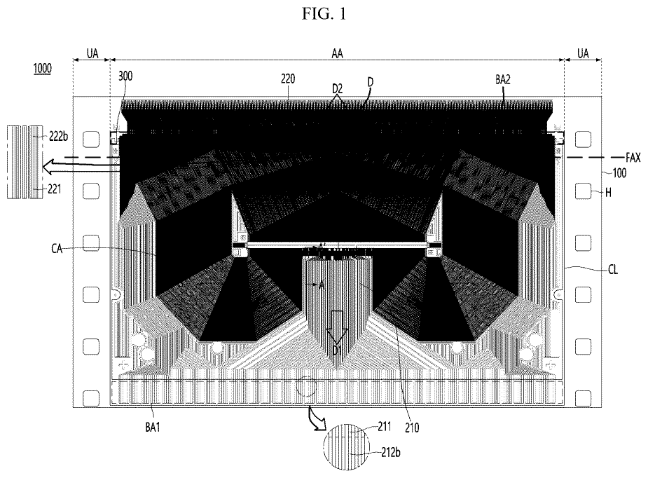

FIG. 1 is a top view of a flexible circuit board according to an embodiment.

Referring to FIG. 1, the flexible circuit board 1000 includes a substrate 100 and a circuit pattern 200 disposed on the substrate 100.

The substrate 100 includes a first surface 1S and a second surface 2S opposite to the first surface IS.

The substrate 100 may include a flexible substrate. For example, the substrate 100 may be a polyimide (PI) substrate. However, the embodiment is not limited thereto. The substrate 100 may include polyethylene terephthalate (PET) or polyethylene naphthalate (PEN). Accordingly, the flexible circuit board can be used in various electronic devices. For example, the flexible circuit board has excellent flexible characteristics. Therefore, the flexible circuit board can be applied to wearable electronic devices.

The substrate 100 can have a thickness of 20 μm to 100 μm. For example, the substrate 100 can have a thickness of 25 μm to 50 μm. For example, the substrate 100 can have a thickness of 30 μm to 40 μm. If the thickness of the substrate 100 exceeds 100 μm, the overall thickness of the flexible circuit board can increase. Accordingly, the flexible characteristics of the flexible circuit board are reduced. In addition, if the thickness of the substrate 100 is less than 20 am, the rigidity of the substrate can be reduced. Accordingly, When mounting a chip on the substrate, the substrate 100 may be damaged by heat and pressure.

The substrate 100 includes an effective region UA and an ineffective region UA. The effective region AA may be a central region of the substrate 100. The ineffective region UA may be an edge region of the substrate 100. The ineffective region UA may surround the effective region AA.

The effective region AA includes a chip mounting region CA. In detail, the chip mounting region CA is a region where a chip (C) connected to the circuit pattern is mounted.

In addition, a circuit pattern 210 and 220 is disposed on the effective region AA. In detail, the circuit pattern includes a plurality of circuit patterns. The plurality of circuit patterns extend in a plurality of directions. In addition, the plurality of circuit patterns are spaced apart from each other.

The effective region AA is a region that is actually used in the flexible circuit board 1000.

The circuit pattern is not disposed in the ineffective region UA. That is, the effective region AA and the ineffective region UA are distinguished by whether the circuit pattern is disposed.

The ineffective region UA includes a plurality of holes. In detail, the ineffective region UA includes a plurality of sprocket holes H. The flexible circuit board is rolled or unrolled in a roll-to-roll manner by the sprocket holes.

The ineffective region UA is a region that is not actually used in the flexible circuit board 1000. In detail, the ineffective region UA is a region that is removed after manufacturing the COF module.

In detail, a boundary between the effective region AA and the ineffective region UA is defined by a cutting line CL. The flexible circuit board 1000 is processed into a COF module after cutting the cutting line CL. Accordingly, the flexible circuit board 1000 is applied to various electronic devices.

The circuit pattern includes a wiring part and a pad part. In addition, a plurality of circuit patterns are disposed in the effective region AA. In detail, a first circuit pattern 210 and a second circuit pattern 220 are disposed in the effective region AA. The first circuit pattern 210 and the second circuit pattern 220 are disposed on the first surface 1S.

Referring to FIGS. 1 to 3, the first circuit pattern 210 includes a first wiring part 211, a first pad part 212a, and a second pad part 212b. The first pad part 212a is disposed inside the chip mounting region CA. The second pad part 212b is disposed outside the chip mounting region CA. The first wiring part 211 is disposed between the first pad part 212a and the second pad part 212b. The first wiring part 211 is connected to the first pad part 212a and the second pad part 212b.

The first wiring part 211, the first pad part 212a, and the second pad part 212b may be formed integrally.

In addition, the first wiring part 211 may extend in a first direction D1 based on the chip mounting region CA.

The first pad part 212a is electrically connected to a chip disposed in the chip mounting region. In addition, the second pad part 212b is electrically connected to a printed circuit board. In addition, the first wiring part 211 transmits a signal between the chip and the printed circuit board.

A protective layer 300 is disposed on the first circuit pattern 210. In detail, the protective layer 300 is disposed on the first wiring part 211. The protective layer 300 surrounds the first wiring part 211. In addition, the protective layer 300 is not disposed on the first pad part 212a and the second pad part 212b. Accordingly, the first pad part 212a and the second pad part 212b are exposed to an outside.

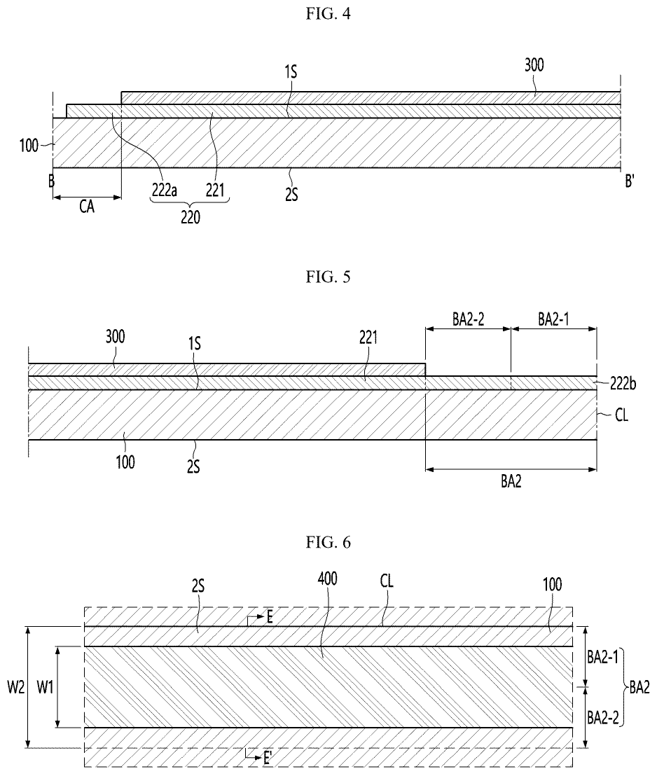

In addition, referring to FIG. 1 and FIG. 4, the second circuit pattern 220 includes the second wiring part 221, the third pad part 222a, and the fourth pad part 222b. The third pad part 222a is disposed inside the chip mounting region CA. The fourth pad part 222b is disposed outside the chip mounting region CA. The second wiring part 221 is disposed between the third pad part 222a and the fourth pad part 222b. The second wiring part 221 is connected to the third pad part 222a and the fourth pad part 222b.

The second wiring part 221, the third pad part 222a, and the fourth pad part 222b may be formed integrally.

In addition, the second wiring part 221 may extend in a second direction D2 based on the chip mounting region CA. In detail, the second direction 2D is an opposite direction to the first direction D1.

The third pad part 222a is electrically connected to a chip disposed in the chip mounting region. In addition, the fourth pad part 222b is electrically connected to a display panel. In addition, the second wiring part 221 transmits a signal between the chip and the display panel.

A protective layer 300 may be disposed on the second circuit pattern 220. In detail, the protective layer 300 is disposed on the second wiring part 221. The protective layer 300 surrounds the second wiring part 221. In addition, the protective layer 300 is not disposed on the third pad part 222a and the fourth pad part 222b. Accordingly, the third pad part 222a and the fourth pad part 222b are exposed to the outside.

The first circuit pattern 210 and the second circuit pattern 220 may include a metal material. In detail, the first circuit pattern 210 and the second circuit pattern 220 may include copper (Cu). However, the embodiment is not limited thereto. The first circuit pattern 210 and the second circuit pattern 220 may include at least one metal among copper (Cu), aluminum (Al), chromium (Cr), nickel (Ni), silver (Ag), molybdenum (Mo), gold (Au), titanium (Ti), and alloys thereof.

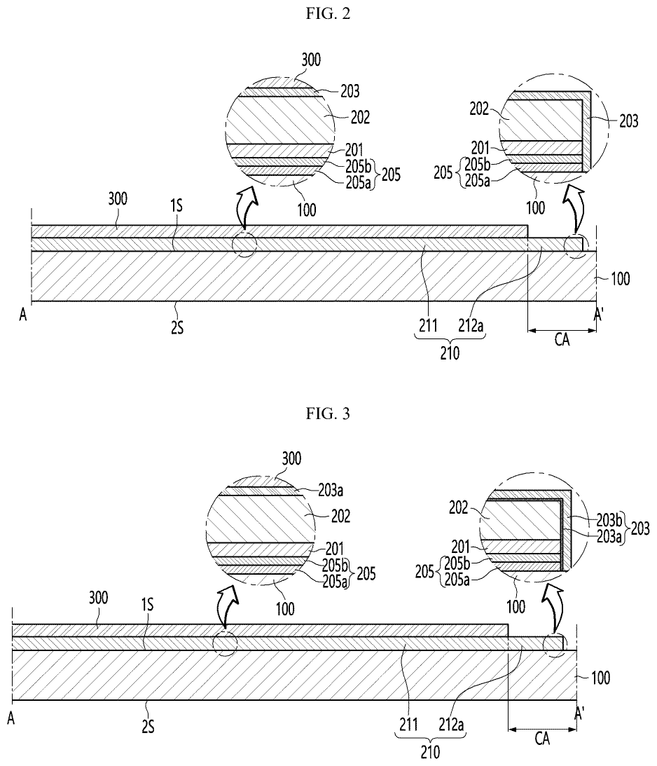

Hereinafter, the layer structure of the circuit pattern will be described with reference to FIGS. 2 and 3. In FIGS. 2 and 3, the description will be based on the first circuit pattern 210. However, the embodiment is not limited thereto. A description described in FIGS. 2 and 3 can be equally applied to the second circuit pattern 220.

Referring to FIG. 2, the first circuit pattern 210 is formed in multiple layers. In detail, the first wiring part 211 and the first pad part 212a include a first metal layer 201 and a second metal layer 202. In addition, although not shown in the drawing, the second pad part 212b also includes the first metal layer 201 and the second metal layer 202.

The first metal layer 201 is a seed layer of the first circuit pattern 210. In detail, the first metal layer 201 is a seed layer formed through electroless plating. The seed layer includes a metal material. For example, the seed layer may include copper.

In addition, the second metal layer 202 is a plating layer. In detail, the second metal layer 202 is a plating layer formed by electroplating using the first metal layer 201 as a seed layer.

A thickness of the first metal layer 201 is smaller than a thickness of the second metal layer 202.

For example, a thickness of the first metal layer 201 may be 0.7 μm to 2 μm. In addition, a thickness of the second metal layer 202 may be 10 μm to 25 μm.

The first metal layer 201 and the second metal layer 202 may include a same metal material. For example, the first metal layer 201 and the second metal layer 202 may include copper (Cu).

A bonding layer 203 may be disposed on the second metal layer 201. In detail, the bonding layer 203 is disposed on a side surface of the first metal layer 201, a side surface of the second metal layer 202, and an upper surface of the second metal layer 202. That is, the bonding layer 203 surrounds the first metal layer 201 and the second metal layer 202.

The bonding layer 203 includes a metal. For example, the bonding layer 203 may include tin (Sn).

A thickness of the bonding layer 203 may be 0.3 μm to 0.7 μm. The bonding layer 203 may increase the tin content as the bonding layer extends from a lower surface of the bonding layer to an upper surface of the bonding layer. The lower surface of the bonding layer 203 is a surface in which the second metal layer 202 contacts.

Since the bonding layer 203 and the second metal layer 202 are in contact with each other, a content of tin in the bonding layer 203 increases and a content of copper decreases as the bonding layer extends from a lower surface of the bonding layer to an upper surface of the bonding layer.

Accordingly, only pure tin can remain in a thickness range of 0.1 μm to 0.3 μm on the upper surface of the bonding layer 203.

By the bonding layer 203, a terminal of the chip, a terminal of the printed circuit board, and a terminal of the display panel are easily bonded to the first pad part and the second pad part. In detail, the terminals and the pad parts are bonded by heat and pressure. That is, when heat and pressure are applied to the first pad part and the second pad part, the upper surface where pure tin remains in the bonding layer is melted. As a result, the terminals and the pad parts are easily bonded.

Accordingly, the bonding layer 203 is not separated from the first pad part 212a, but becomes a part of the first pad part 212a.

A thickness of the first circuit pattern 210 may be 2 μm to 25 μm. For example, the thickness of the first circuit pattern 210 may be 5 μm to 20 μm. For example, the thickness of the first circuit pattern 210 may be 7 μm to 15 μm.

The thickness of the first circuit pattern 210 may be different from a sum of the thicknesses of the first metal layer 201, the second metal layer 202, and the bonding layer 203. In detail, a flash etching process is performed during the manufacturing process to separate the circuit patterns. Therefore, the first metal layer 201 is etched. Accordingly, the thickness of the first circuit pattern 210 finally manufactured is smaller than the sum of the thicknesses of the first metal layer 201, the second metal layer 202, and the bonding layer 203.

If the thickness of the first circuit pattern 210 and the second circuit pattern 220 is less than 2 μm, a resistance of the first circuit pattern 210 and the second circuit pattern 220 increases. If the thickness of the first circuit pattern 210 and the second circuit pattern 220 exceeds 25 μm, it is difficult to form a fine pattern.

Meanwhile, a buffer layer 205 may be further disposed between the substrate 100 and the first circuit pattern 210. The adhesion between the substrate 100 and the first circuit pattern 210 is improved by the buffer layer 205.

The buffer layer 205 may be formed in multiple layers. In detail, the buffer layer 205 includes a first buffer layer 205a and a second buffer layer 205b on the first buffer layer 205a. Accordingly, the first buffer layer 205a is in contact with the substrate 100. In addition, the second buffer layer 205b is in contact with the first circuit pattern 201.

The first buffer layer 205a may include a material having good adhesion to the substrate 100. For example, the first buffer layer 205a may include nickel (Ni). In addition, the second buffer layer 205b may include a material having good adhesion to the first circuit pattern 210. For example, the second buffer layer 205b may include chromium (Cr).

The buffer layer 205 may have a thin film thickness in nanometer units. For example, the thickness of the buffer layer 205 may be 20 nm or less.

The adhesion between the substrate 100 and the first circuit pattern 210 is improved by the buffer layer 205. Therefore, the peeling of the first circuit pattern 201 is prevented.

Meanwhile, referring to FIG. 3, the bonding layer 203 may include a first bonding layer 203a and a second bonding layer 203b.

In detail, the first bonding layer 203a may be disposed on the first wiring part 211 and the first pad part 212a. In addition, although not shown in the drawing, the first bonding layer 203a may also be disposed on the second pad part 212b. That is, the first bonding layer 203a may be disposed on the first circuit pattern 210.

In addition, the second bonding layer 203b may be disposed only on the first pad part 212a and the second pad part 212b. That is, a layer structure of the first wiring part 211 and layer structures of the first pad part 212a and the second pad part 212b are changed by the second bonding layer 203b.

The first bonding layer 203a and the second bonding layer 203b may include a metal. In detail, the first bonding layer 203a and the second bonding layer 203b may include tin (Sn).

The first bonding layer 203a and the second bonding layer 203b may have different thicknesses. In detail, a thickness of the second bonding layer 203b may be greater than a thickness of the first bonding layer 203a.

For example, the first bonding layer 203a may have a film thickness of 0.02 μm to 0.06 μm. In addition, the thickness of the second bonding layer 203b may be 0.2 μm to 0.6 μm.

If the bonding layer is thickly disposed between the protective layer 300 and the first wiring part 211, cracks may occur when the flexible circuit board is bent. Accordingly, the first bonding layer 231 between the protective layer 300 and the first wiring part 211 is formed with a thin film thickness. Therefore, cracks may be prevented from occurring when the flexible circuit board is bent.

In addition, the second bonding layer 203b may have a high tin content while extending from the lower surface to the upper surface. The lower surface is a surface in which contacts the first bonding layer 203a.

The second bonding layer 203b may have a higher tin content and a lower copper content as it extends from the lower surface to the upper surface. Accordingly, only pure tin may remain in the second bonding layer 203b in a thickness range of 0.1 μm to 0.3 μm on the upper surface.

By the second bonding layer 203b, the terminal of the chip, the terminal of the printed circuit board, and the terminal of the display panel are easily bonded to the first pad part and the second pad part. In detail, the terminals and the pad parts are bonded by heat and pressure. That is, when heat and pressure are applied to the first pad part and the second pad part, the upper surface where pure tin remains in the bonding layer is melted. As a result, the terminals and the pad parts are easily bonded.

Accordingly, the first bonding layer 203a and the second bonding layer 203b are not separated from the first pad part 212a, but become a part of the first pad part.

Meanwhile, the protective layer 300 is disposed on the wiring part of the first circuit pattern 210 and the wiring part of the second circuit pattern 220. In detail, the protective layer 300 surrounds the first wiring part 211 and the second wiring part 221. That is, the protective layer 300 can be disposed on the first circuit pattern 210 and the second circuit pattern 220 except for the first pad part, the second pad part, the third pad part, and the fourth pad part.

The protective layer 300 can include a solder paste. For example, the solder paste may include a thermosetting resin, a thermoplastic resin, a filler, a curing agent, or a curing accelerator.

Meanwhile, in the above description, the first circuit pattern 210 and the second circuit pattern 220 are described as being disposed on a same surface of the substrate 100, but the embodiment is not limited thereto.

In detail, the first circuit pattern 210 and the second circuit pattern 220 may be disposed on different surfaces of the substrate 100. For example, the first circuit pattern 210 may be disposed on one surface of the substrate 100, and the second circuit pattern 220 may be disposed on other surface opposite to the one surface of the substrate 100.

Accordingly, the display panel is connected to the chip on one surface of the substrate 100. In addition, the printed circuit board is connected to the chip on the other surface of the substrate 100.

Referring to FIG. 1, the flexible circuit board 1000 includes a first bonding region BA1 and a second bonding region BA2.

The second pad part 212b is disposed on the first bonding region BAL. In addition, the fourth pad part 222b is disposed on the second bonding region BA2. That is, the protective layer 300 is not disposed on the first bonding region BA1 and the second bonding region BA2.

The printed circuit board and the display panel are bonded at the first bonding region BA1 and the second bonding region BA2. In detail, the first bonding region BA1 is bonded to a terminal part of the printed circuit board through a conductive adhesive. In addition, the second bonding region BA2 is bonded to a terminal part of the display panel through a conductive adhesive. At this time, a corrosion protection layer may be additionally disposed in a region of the second pad part 212b and the fourth pad part 222b where the conductive adhesive is not disposed among the bonding regions. The corrosion protection layer prevents corrosion of the pad part.

For example, referring to FIG. 5, the second bonding region BA2 may include a second-first bonding region BA2-1 and a second-second bonding region BA2-2. Different materials may be disposed in the second-first bonding region BA2-1 and the second-second bonding region BA2-2.

The second-first bonding region BA2-1 is a region where the conductive adhesive is disposed. In addition, the second-second bonding region BA2-2 is a region where the corrosion protection layer is disposed. In detail, when connecting the fourth pad part 222b and the terminal of the display panel, the conductive adhesive is disposed only on a part of the fourth pad part 222b. Accordingly, a region where the fourth pad part 222b is exposed occurs. The exposed region is defined as the second-second bonding region BA2-2. Accordingly, a corrosion protection layer is disposed on the second-second bonding region BA2-2. Accordingly, corrosion of the second-second bonding region BA2-2 is prevented.

Meanwhile, the flexible circuit board 1000 is bent in one direction. In detail, the flexible circuit board 1000 is bent in one direction with a folding axis FAX as an axis. Accordingly, the stress generated by the bending is transmitted to the second bonding region. The corrosion protection layer disposed in the second-second bonding region BA2-2 may be peeled off due to the stress. That is, the corrosion protection layer has a lower adhesive strength than the conductive adhesive. Therefore, it may be peeled off from the pad part due to the stress.

Accordingly, the stress is transmitted from a boundary region of the second-first bonding region BA2-1 and the second-second bonding region BA2-2 to the fourth pad part. In addition, a crack may occur in the fourth pad part corresponding to the boundary region. Accordingly, the reliability of the flexible circuit board may be reduced.

Accordingly, the flexible circuit board according to the embodiment solves the above problem by additionally arranging a dummy pattern.

In addition, the dummy pattern prevents peeling of the corrosion protection layer on the second-second bonding region.

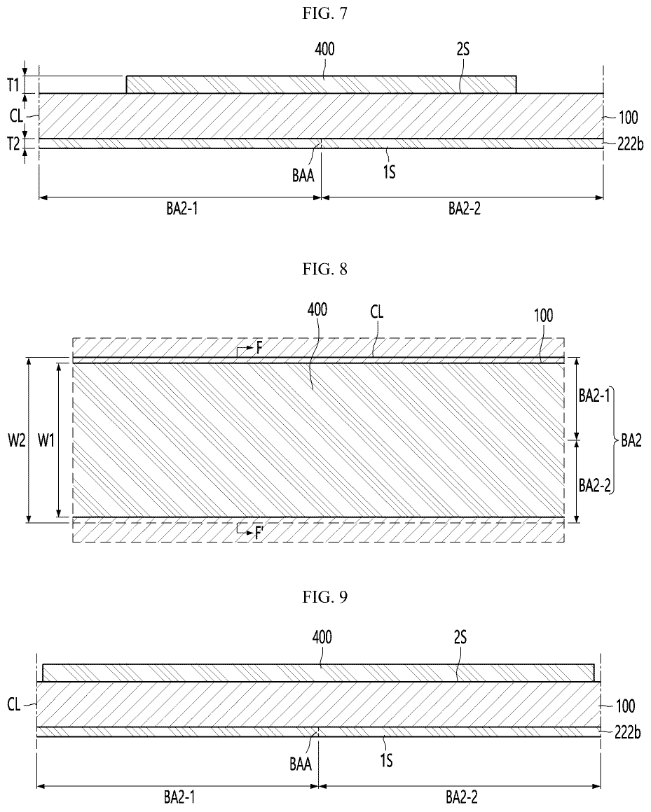

Referring to FIGS. 6 and 7, a dummy pattern 400 is disposed on the second surface 2S. The dummy pattern 400 is disposed at a position overlapping the fourth pad part 222b. In detail, the dummy pattern 400 partially overlaps the fourth pad part 222b. The dummy pattern 400 is disposed to be smaller than an area of the second bonding region BA2 on which the fourth pad part 222b is disposed. For example, a width W1 of the dummy pattern 400 may be 50% or more, 60% or more, or 70% or more of a width W2 of the second bonding region BA2. For example, the width W1 of the dummy pattern 400 may be 50% to less than 90% of the width W2 of the second bonding region BA2.

In addition, an area of the dummy pattern 400 may be 50% or more, 60% or more, or 70% or more of the area of the second bonding region BA2 or the fourth pad part 222b. For example, the area of the dummy pattern 400 may be 50% to less than 90% of the area of the second bonding region BA2 or the fourth pad part 222b.

A total area of the dummy pattern in the second bonding region may be larger than a total area of the fourth pad part. The fourth pad part includes a plurality of fourth pad parts spaced apart from each other. The plurality of fourth pad parts are electrically connected to the terminal part of the display panel, respectively. However, the dummy pattern is disposed to prevent cracks in the fourth pad part. Therefore, even if a spacing between the plurality of dummy patterns are small, the characteristics do not decrease. In addition, even if the plurality of dummy patterns are connected, the characteristics do not decrease. Alternatively, the dummy pattern may be formed on the entire surface of the second bonding region.

The dummy pattern 400 is disposed to be smaller than an area of the second bonding region BA2 or the fourth pad part 222b. Therefore, a difference in strength between the boundary region of the second-first bonding region BA2-1 and the second-second bonding region BA2-2 and the second-first bonding region BA2-1 is reduced. In addition, a difference in strength between the boundary region of the second-first bonding region BA2-1 and the second-second bonding region BA2-2 and the second-second bonding region BA2-2 is reduced. Accordingly, the flexible printed circuit board can be prevented from being bent by the dummy pattern 400.

The dummy pattern 400 is disposed at a position overlapping the second-first bonding region BA2-1 and the second-second bonding region BA2-2. In addition, the dummy pattern 400 is disposed on the boundary region BAA of the second-first bonding region BA2-1 and the second-second bonding region BA2-2.

The adhesion of the conductive adhesive and the corrosion protection layer disposed on the fourth pad part 222b can be improved by the dummy pattern 400. That is, since the dummy pattern 400 is disposed on the boundary region BAA of the second-first bonding region BA2-1 and the second-second bonding region BA2-2, cracks can be prevented from occurring in the fourth pad part. In addition, the conductive adhesive and corrosion protection layer disposed in the second-first bonding region BA2-1 and the second-second bonding region BA2-2 can be prevented from being peeled off. In particular, the corrosion protection layer having low adhesive strength can be prevented from being peeled off from the pad part.

The dummy pattern 400 serves to support the boundary region of the conductive adhesive and the corrosion protection layer. Accordingly, when the flexible circuit board is bent, the corrosion protection layer can be prevented from being peeled off at the boundary region.

Accordingly, the fourth pad part can be prevented from being exposed to an outside due to the peeling of the corrosion protection layer. In addition, the fourth pad part can be prevented from being cracked due to the stress.

The dummy pattern 400 can include copper (Cu). However, the embodiment is not limited thereto. The dummy pattern 400 may include at least one metal among copper (Cu), aluminum (Al), chromium (Cr), nickel (Ni), silver (Ag), molybdenum (Mo), gold (Au), titanium (Ti), and alloys thereof.

The dummy pattern 400 is not connected to the chip (C). That is, the signal does not move through the dummy pattern 400.

The embodiment has a layer structure similar to a double-sided flexible circuit board in which a circuit pattern is formed on both sides of the substrate. However, a through hole and a through electrode are not separately formed in the substrate. Therefore, the manufacturing cost and defects are reduced, and thus the process efficiency is improved.

In addition, the embodiment has a layer structure similar to a flexible circuit board in which a circuit is formed on one side of the substrate and a heat dissipation pattern is formed on the other side. However, the heat dissipation pattern is formed in a region corresponding to a chip mounting region. However, the dummy pattern of the embodiment is formed in a second bonding region that contacts the display. In detail, the dummy pattern is formed between the bending region of the flexible circuit board and the second bonding region, and therefore, it does not affect the bending characteristics when bending the flexible circuit board. Therefore, the design reliability and the reliability of the display can be improved. In addition, the embodiment may additionally place a separate heat dissipation pattern different from the dummy pattern in a region corresponding to the chip mounting region.

The dummy pattern may overlap with the fourth pad part 222b, and the heat dissipation pattern may be formed on a second surface overlapping with the chip mounting region. In addition, the dummy pattern and the heat dissipation pattern may be disposed in a region that does not correspond to the folding axis FAX. If the dummy pattern or the heat dissipation pattern is formed in a region corresponding to the folding axis FAX, when the flexible circuit board and the display are combined and then bent, a crack may occur in the dummy pattern or the heat dissipation pattern. Accordingly, the reliability of the flexible circuit board may decrease.

The dummy pattern 400 may include a same material as at least one of the first circuit pattern 210 and the second circuit pattern 220. Accordingly, a difference in thermal expansion coefficients between the first surface 1S and the second surface 2S of the substrate 100 may be reduced.

The thicknesses of the dummy pattern 400 and the fourth pad part 222b may be the same. Alternatively, the thicknesses of the dummy pattern 400 and the fourth pad part 222b may be different. For example, the thickness T1 of the dummy pattern 400 may be smaller than the thickness T2 of the fourth pad part 222b. The dummy pattern 400 may not form a bonding layer 203 of the fourth pad part. Accordingly, the manufacturing cost of the flexible circuit board may be reduced. For example, the thickness T1 of the dummy pattern 400 may be greater than the thickness T2 of the fourth pad part 222b. Accordingly, the dummy pattern 400 may stably support the fourth pad part 222b on the second surface 2S. Therefore, stress concentration may be prevented.

Referring to FIGS. 8 and 9, the dummy pattern 400 may be positioned at a position that overlaps the fourth pad part 222b. In detail, an area of the dummy pattern 400 may be the same as or similar to the area of the second bonding region BA2. For example, a width W1 of the dummy pattern 400 may be 90% or more, 93% or more, or 95% or more of a width W2 of the second bonding region BA2. In detail, the width W1 of the dummy pattern 400 may be 90% to 110% of the width W2 of the second bonding region BA2.

In addition, the area of the dummy pattern 400 may be 90% or more, 93% or more, or 95% or more of the area of the second bonding region BA2 or the fourth pad part 222b. The area of the dummy pattern 400 may be 110% or less, 107% or less, or 105% or less of the area of the second bonding region BA2 or the fourth pad part 222b. In detail, the area of the dummy pattern 400 may be 90% to 110% of the area of the second bonding region BA2 or the fourth pad part 222b.

The dummy pattern 400 is disposed to be almost identical to the area of the second bonding region BA2 or the fourth pad part 222b. Therefore, the dummy pattern 400 can stably support the second bonding region BA2. That is, the dummy pattern 400 is disposed on almost the entire region of the second bonding region BA2. Therefore, it is possible to prevent the crack of the fourth pad part and the corrosion protection layer from being peeled off by the stress generated in the second bonding region.

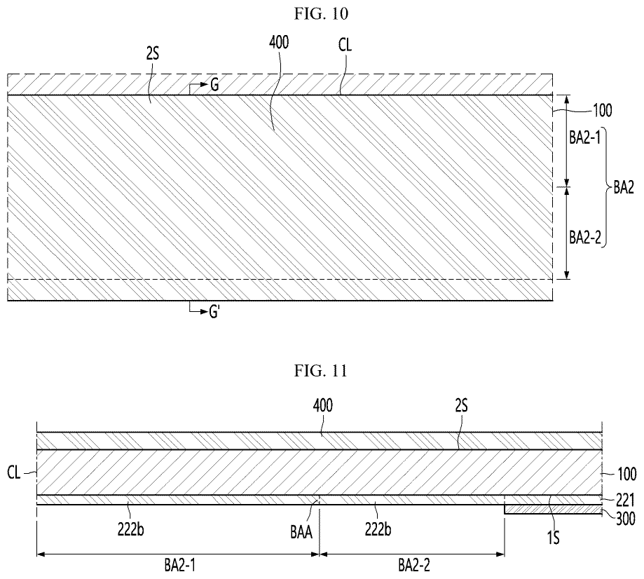

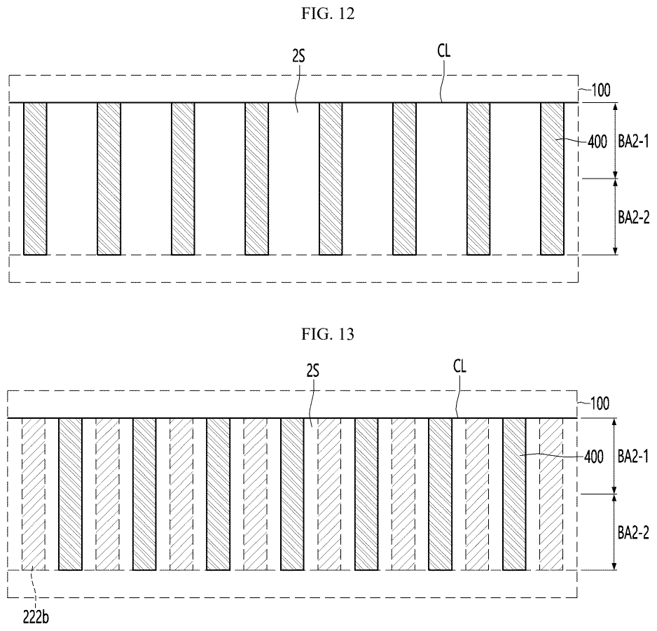

Referring to FIGS. 10 and 11, the dummy pattern 400 can be disposed at a position overlapping the fourth pad part 222b. In detail, the area of the dummy pattern 400 can be larger than the area of the second bonding region BA2 or the fourth pad part 222b. That is, the dummy pattern 400 can be disposed at a position overlapping the fourth pad part 222b and the second wiring part 221. In detail, the dummy pattern 400 entirely overlaps the second bonding region BA2 where the fourth pad part 222b is disposed. In addition, the dummy pattern 400 partially overlaps a region where the second wiring part 221 is disposed. One side of the dummy pattern 400 may be formed identically or close to the cutting line CL. In addition, other side of the dummy pattern 400 may be disposed closer to the fourth pad part 222b than the folding axis FAX.

The dummy pattern 400 overlaps the second wiring part 221 between the folding axis FAX and the fourth pad part 222b. In addition, the dummy pattern 400 is not formed in a region corresponding to the folding axis FAX. Accordingly, when the flexible circuit board is combined with the display and bent, it is possible to prevent a crack from occurring in the dummy pattern 400 due to tension occurring in a region of the second surface corresponding to the folding axis FAX. Accordingly, the reliability of the display can be improved.

The dummy pattern 400 is larger than the area of the second bonding region BA2. Therefore, the difference in strength between the boundary region of the fourth pad part 222b and the second wiring part 221 can be reduced. In addition, the difference in strength between the boundary region of the fourth pad part 222b and the protective layer can be reduced. That is, the dummy pattern 400 is also disposed in a region overlapping the second wiring part. Therefore, it is possible to prevent a difference in strength from occurring in a boundary region of the fourth pad part 222b and the second wiring part 221 and a boundary region of the fourth pad part 222b and the protective layer. Accordingly, it is possible to prevent cracks from occurring in the wiring part due to the flexible circuit board being bent at the boundary region between the pad part and the wiring part. In addition, it is possible to prevent peeling of the protective layer and the corrosion protection layer.

Meanwhile, in FIGS. 6 to 11, only the dummy pattern 400 is illustrated as being disposed on the second surface 2S. However, the embodiment is not limited thereto. In detail, an additional protective layer may be disposed on the dummy pattern 400. For example, the additional protective layer may surround the dummy pattern 400. Accordingly, corrosion of the dummy pattern 400 may be prevented.

The flexible circuit board according to the embodiment includes a dummy pattern. The reliability of the flexible circuit board is improved by the dummy pattern. When the flexible circuit board is bent, stress is transmitted to the fourth pad part. The dummy pattern may prevent the corrosion protection layer from being peeled off. In addition, it is possible to prevent cracks from occurring in the pad part.

In addition, the width of the dummy pattern may be smaller than a minimum length of the second circuit pattern. If the width of the dummy pattern is larger than a minimum length of the second circuit pattern, the dummy pattern is formed on most of the lower surface of the substrate, thereby reducing the flexibility of the flexible circuit board. Accordingly, the bending characteristics of the flexible circuit board are reduced. Accordingly, a thickness of the display panel may increase. Alternatively, additional cracks may occur as the dummy pattern formed on the second surface increases. Accordingly, the reliability of the flexible circuit board may be reduced.

Meanwhile, the dummy pattern may be formed as a pattern of various shapes.

Referring to FIGS. 12 to 14, the dummy pattern 400 may include a plurality of patterns spaced apart from each other.

Referring to FIG. 12, the dummy pattern 400 may overlap with the fourth pad part 222b. In detail, the dummy pattern 400 and the fourth pad part 222b may overlap in a thickness direction of the substrate 100. In detail, the dummy pattern 400 and the fourth pad part 222b may overlap completely or partially in the thickness direction of the substrate 100.

For example, the dummy pattern 400 may be disposed on the second surface 2S in a region corresponding to the fourth pad part 222b on the first surface 1S.

Alternately, referring to FIG. 13, the dummy pattern 400 may be disposed to be staggered from the fourth pad part 222b. In detail, the dummy pattern 400 may be disposed on the second surface 2S corresponding to a separation region between the fourth pad parts 222b. That is, the dummy pattern 400 and the fourth pad part 222b do not overlap in the thickness direction of the substrate 100.

In the second bonding region BA2, the dummy pattern 400 and the fourth pad part 222b are disposed in an alternating manner. Therefore, it is possible to prevent waviness from occurring in a region where a copper pattern is not disposed in the first surface iS and the second surface 2S of the second bonding region.

That is, since the dummy pattern 400 and the fourth pad part 222b are disposed in an alternating manner in the second bonding region BA2, a copper pattern is disposed in almost the entire region of the second bonding region BA2. Therefore, the occurrence of waviness in a region where the copper pattern is not disposed can be reduced.

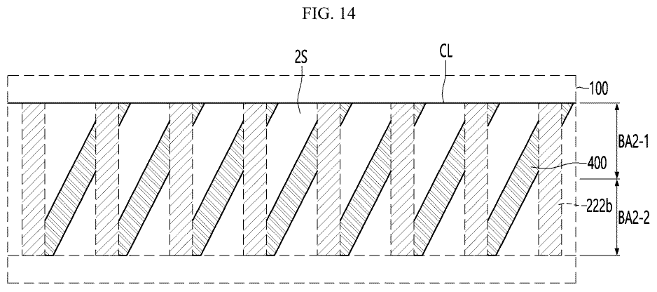

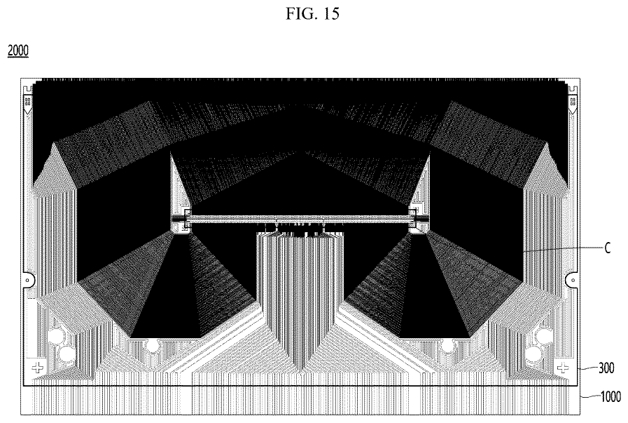

Referring to FIG. 14, the dummy pattern 400 may extend in a different direction from the fourth pad part 222b. That is, a longitudinal direction of the dummy pattern 400 may be different from a longitudinal direction of the fourth pad part 222b. For example, the dummy pattern 400 may extend on the second surface in a diagonal direction forming a certain angle with the fourth pad.

Accordingly, the dummy pattern 400 may partially overlap with the fourth pad part 222b. In addition, the dummy pattern 400 may be disposed to cover a width direction of the separation region of the fourth pad part 222b.

For example, the dummy pattern and the fourth pad part can be vertically overlapped at the boundary region of the second-first bonding region and the second-second bonding region. This can prevent stress from being concentrated at the boundary region. In addition, the width direction of the separation region of the fourth pad parts can be covered together.

Since the dummy pattern 400 is disposed in a diagonal direction, the dummy pattern 400 is disposed while covering the width direction of the separation region of the fourth pad part 222b. Therefore, the dummy pattern 400 can support the fourth pad part 222b in a wider region.

Hereinafter, the present invention will be described in more detail through the bending characteristics of the flexible circuit board according to the embodiments and comparative examples. These embodiments are merely presented as examples in order to describe the present invention in more detail. Therefore, the present invention is not limited to these embodiments.

### EXAMPLE 1

A flexible circuit board is manufactured by forming the first circuit pattern, the second circuit pattern, and the protective layer described above on the first surface of a polyimide (PI) substrate.

Next, a dummy pattern is formed on the second surface corresponding to the second bonding region of the second circuit pattern. At this time, the dummy pattern is disposed on the region corresponding to the fourth pad part as shown in FIG. 12.

Next, the bending characteristics of the flexible circuit board are measured. The bending characteristics measure the number of bending at which cracks occur in the second pad part when the flexible circuit board is bent.

### EXAMPLE 2

A flexible circuit board is manufactured in the same manner as in Example 1, except that the dummy pattern is disposed alternately with the fourth pad part as shown in FIG. 13, and the bending characteristics of the flexible circuit board are measured.

### EXAMPLE 3

A flexible circuit board is manufactured in the same manner as in Example 1, except that the dummy patterns are all disposed on the regions corresponding to the second bonding regions as in FIG. 8, and the bending characteristics of the flexible circuit board are measured.

### EXAMPLE 4

A flexible circuit board is manufactured in the same manner as in Example 1, except that the dummy patterns are disposed in a diagonal pattern on the regions corresponding to the second bonding regions as in FIG. 14, and the bending characteristics of the flexible circuit board are measured.

### COMPARATIVE EXAMPLE

A flexible circuit board is manufactured in the same manner as in Example 1, except that the dummy patterns are not disposed, and the bending characteristics of the flexible circuit board are measured.

TABLE 1

| | | | | | Com- |
|---|---|---|---|---|---|
| | Ex- | Ex- | Ex- | Ex- | parative |
| | ample 1 | ample 2 | ample 3 | ample 4 | example |
| Bending | 93 | 91 | 108 | 93 | 75 |
| characteristics | | | | | |
| (number of | | | | | |
| bends before | | | | | |
| cracks occur) | | | | | |

Referring to Table 1, the flexible circuit boards of Examples 1 to 4 have improved bending characteristics compared to the flexible circuit boards of Comparative Examples. That is, the flexible circuit boards of Examples 1 to 4 include a dummy pattern. The dummy pattern can prevent cracking of the second pad part due to stress during bending. Accordingly, damage to the second pad part due to the stress can be reduced by the dummy pattern. Therefore, the flexible circuit board according to the embodiment can have improved reliability.

FIG. 15 is a drawing illustrating a top view of a COF module according to the embodiment.

Referring to FIG. 15, the COF module includes the flexible circuit board described above. In addition, it may include a chip (C) disposed in the chip mounting region CA.

In addition, the flexible circuit board 1000 may include the protective layer 300 described above.

Meanwhile, the COF module 2000 is manufactured by cutting the flexible circuit board 1000 and then mounting the chip (C). In detail, after cutting along the cutting line CL of FIG. 1, a driving chip electrically connected to the first circuit pattern and the second circuit pattern is mounted in the chip mounting region.

The COF module is located between the display panel and the substrate and can transmit an electrical signal.

That is, the pad parts of the first circuit pattern and the second circuit pattern can be connected to the display panel, the printed circuit board, and the chip.

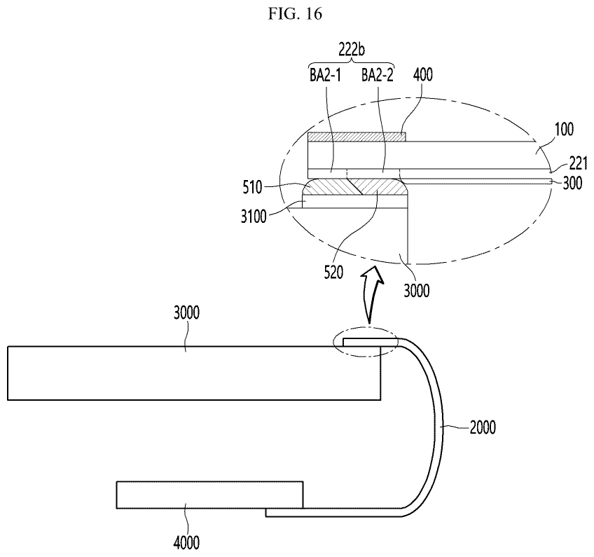

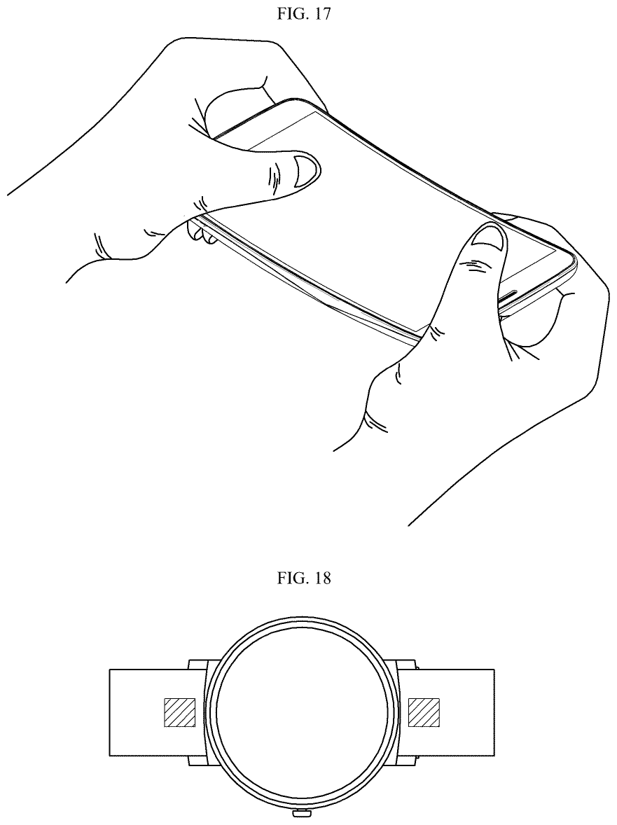

Referring to FIG. 16, one end of the COF module 2000 is connected to the display panel 3000. In addition, other end of the COF module 2000 is connected to the printed circuit board 4000.

In addition, the COF module 2000 and a terminal 3100 of the display panel 3000 can be bonded by a conductive adhesive 510 and a corrosion protection layer 520. In detail, the second-first bonding region BA2-1 of the COF module and a terminal 3100 of the display panel 3000 are bonded by the conductive adhesive 510.

The COF module 2000 and the display panel 3000 can be electrically connected by the conductive adhesive. The conductive adhesive is a resin in which conductive particles are dispersed. Therefore, a signal of the display panel 3000 can be transmitted to the COF module 2000 by the conductive particles.

Next, a corrosion protection layer 520 is disposed on the second-second bonding region BA2-2. By this, corrosion of an exposed region of the fourth pad part 222b can be prevented.

In addition, a dummy pattern 400 is disposed on the substrate 100. Therefore, when the COF module 2000 is bent, the corrosion protection layer 520 can be peeled off, and cracks can be prevented from occurring in the fourth pad part 222b.

The COF module 1000 includes a flexible substrate. Therefore, it can have a rigid shape or a bent shape between the display panel 3000 and the printed circuit board 4000.

The COF module 2000 can connect the display panel 3000 and the printed circuit board 4000 that are disposed to face each other in a bent shape. Therefore, a thickness of the electronic device is reduced, and the design freedom is improved. In addition, the COF module 2000 does not have wire breakage even in a bent form. Therefore, the reliability of the electronic device is improved.

Since the COF module is flexible, it can be used in various electronic devices.

For example, referring to FIG. 17, the COF module can be applied to a flexible touch window that bends. The flexible touch window can be applied to a wearable touch.

Referring to FIG. 18, the COF module can be applied to a wearable touch device including a curved display. Therefore, an electronic device including the COF module can be slimmed down or made lightweight.

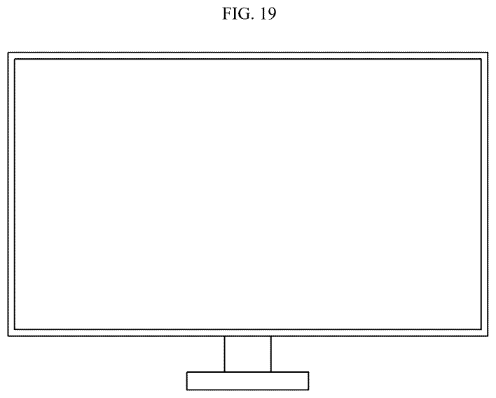

Referring to FIG. 19, the COF module can be applied to various electronic devices having a display such as a TV, a monitor, and a laptop.

However, the embodiment is not limited thereto. The COF flexible circuit board and the COF module can be used in various electronic devices.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A flexible circuit board comprising:
a substrate including a first surface and a second surface opposite to the first surface;
a circuit pattern disposed on the first surface of the substrate; and
a protective layer disposed on the circuit pattern,
wherein the protective laver includes a first open portion corresponding to a chip mounting region, and a second open portion spaced apart from the first open portion and provided between one end of the substrate and one end of the protective layer,
wherein circuit pattern includes an inner pad part disposed in the first open portion, an outer pad part disposed in the second open portion and a wiring part connecting the inner pad part and the outer pad part,
wherein the second surface of the substrate includes an overlapping region overlapping the second open portion in a thickness direction, and
wherein a dummy pattern is disposed in the overlapping region of the second surface of the substrate to extend to the one end of the substrate.

2. The flexible circuit board of claim 1,
comprising:
a corrosion protection layer disposed on the outer pad part,
wherein the outer pad part includes a first portion covered with the corrosion prevention layer and a second portion not covered with the corrosion prevention layer,
wherein the overlapping region includes a first overlapping region overlapping the first portion and a second overlapping region overlapping the second portion, and
wherein the dummy pattern is disposed in a boundary region between the first overlapping region and the second overlapping region.

3. The flexible circuit board of claim 1, wherein a width of the dummy pattern is different from a width of the overlapping region.

4. The flexible circuit board of claim 3, wherein a width of the dummy pattern is larger or smaller than a width of the overlapping region.

5. The flexible circuit board of claim 1, wherein the dummy pattern and the circuit pattern include a same material.

6. The flexible circuit board of claim 1, wherein the dummy pattern is disposed to overlap the outer pad part in a thickness direction of the substrate.

7. The flexible circuit board of claim 1, wherein a thickness of the dummy pattern and a thickness of the outer pad part are different.

8. The flexible circuit board of claim 1, wherein the dummy pattern and the outer pad part extend in a same direction.

9-10. (canceled)

11. The flexible circuit board of claim 1, wherein the dummy pattern does not overlap the outer pad part along a thickness direction.

12. The flexible circuit board of claim 1, wherein the dummy pattern and the outer pad part are disposed and extended in different directions from each other.

13. The flexible circuit board of claim 12, wherein the outer pad part is disposed and extended in a first horizontal direction, and
wherein the dummy pattern is disposed and extended in a diagonal direction between the first horizontal direction and a second horizontal direction perpendicular to the first horizontal direction.

14. The flexible circuit board of claim 13, wherein the outer pad part includes a plurality of outer pads spaced apart along the second horizontal direction, and
wherein the dummy pattern is provided in a plurality and spaced apart along the second horizontal direction,
wherein at least one of the plurality of dummy patterns overlaps at least two outer pads along the thickness direction.

15. The flexible circuit board of claim 1, wherein the second surface of the substrate includes a non-overlapping region overlapping with a region between the first open portion and the second open portion in the thickness direction, and
wherein the dummy pattern is disposed in the non-overlapping region.

16. The flexible circuit board of claim 15, wherein the substrate is foldable based on a folding axis provided between the first open portion and the second open portion, and
wherein the dummy pattern does not overlap with the folding axis in the thickness direction.

17. The flexible circuit board of claim 16, wherein the non-overlapping region is a region between the folding axis and the second open portion.

18. A chip on film (COF) module comprising:
a flexible circuit board according to claim 1; and
a chip disposed in the first open portion.

19. An electronic device comprising:
a COF module according to claim 18;
a printed circuit board connected to one end of the COF module; and
a display panel connected to another end of the COF module.
